(19) United States
(12) Patent Application Publication
(10) Pub. No.: US 2024/0386933 A1
(43) Pub. Date: Nov. 21, 2024

(54) ADJUSTING A SENSING VOLTAGE IN MEMORY

(71) Applicant: Micron Technology, Inc., Boise, ID (US)

(72) Inventors: Daniele Vimercati, El Dorado Hills, CA (US); Jonathan J. Strand, Meridian, ID (US); Giovanni Mazzeo, Sacramento, CA (US)

(21) Appl. No.: 18/662,313

(22) Filed: May 13, 2024

Related U.S. Application Data
(60) Provisional application No. 63/466,491, filed on May 15, 2023.

(51) Int. Cl. G11C 11/22

(52) U.S. Cl. CPC G11C 11/2273; G11C 11/2259

(57) ABSTRACT

The present disclosure includes apparatuses, methods, and systems for adjusting a sensing voltage in memory. An embodiment includes a memory having a group of memory cells, wherein a sub-group of the memory cells of the group remain programmed to a same data state, and circuitry configured to determine an amount of charge associated with the memory cells of the sub-group and adjust a voltage used to sense a data state of the memory cells of the group based, at least in part, on the determined amount of charge.

### PRIORITY INFORMATION

This application claims the benefit of U.S. Provisional Application No. 63/466,491, filed on May 15, 2023, the contents of which are incorporated herein by reference.

### TECHNICAL FIELD

The present disclosure relates generally to semiconductor memory and methods, and more particularly, to adjusting a sensing voltage in memory.

### BACKGROUND

Memory devices are typically provided as internal, semiconductor, integrated circuits and/or external removable devices in computers or other electronic devices. There are many different types of memory including volatile and non-volatile memory. Volatile memory can require power to maintain its data and can include random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), ferroelectric random-access memory (FeRAM), resistance variable memory such as phase change random access memory (PCRAM), resistive random access memory (RRAM), magnetic random access memory (MRAM), and programmable conductive memory, among others.

Memory devices can be utilized as volatile and non-volatile memory for a wide range of electronic applications in need of high memory densities, high reliability, and low power consumption. Non-volatile memory may be used in, for example, personal computers, portable memory sticks, solid state drives (SSDs), digital cameras, cellular telephones, portable music players such as MP3 players, and movie players, among other electronic devices.

Memory devices can include memory cells that can store data based on the charge level of a storage element (e.g., a capacitor). Such memory cells can be programmed to store data corresponding to a target data state by varying the charge level of the storage element (e.g., different levels of charge of the capacitor may represent different data sates). For example, sources of an electrical field or energy, such as positive or negative electrical pulses (e.g., positive or negative voltage or current pulses), can be applied to the memory cell (e.g., to the storage element of the cell) for a particular duration to program the cell to a target data state.

A memory cell can be programmed to one of a number of data states. For example, a single level memory cell (SLC) can be programmed to a targeted one of two different data states, which can be represented by the binary units 1 or 0 and can depend on whether the capacitor of the cell is charged or uncharged. As an additional example, some memory cells can be programmed to a targeted one of more than two data states (e.g., 1111, 0111, 0011, 1011, 1001, 0001, 0101, 1101, 1100, 0100, 0000, 1000, 1010, 0010, 0110, and 1110). Such cells may be referred to as multi state memory cells, multiunit cells, or multilevel cells (MLCs). MLCs can provide higher density memories without increasing the number of memory cells since each cell can represent more than one digit (e.g., more than one bit).

### BRIEF DESCRIPTION OF THE DRAWINGS

FIG. 1A illustrates an example of a memory array in accordance with an embodiment of the present disclosure.

FIG. 1B illustrates an example of a memory cell in accordance with an embodiment of the present disclosure.

FIG. 2 illustrates a diagram of a number of threshold voltage distributions and sensing voltages associated with a group of memory cells in accordance with an embodiment of the present disclosure.

FIGS. 3A and 3B illustrate examples of circuitry for adjusting a sensing voltage in memory, in accordance with an embodiment of the present disclosure.

FIG. 4 illustrates an example of circuitry for determining an amount of charge associated with a sub-group of memory cells, in accordance with an embodiment of the present disclosure.

FIGS. 5A and 5B illustrate examples of timing diagrams associated with adjusting a sensing voltage in memory in accordance with an embodiment of the present disclosure.

### DETAILED DESCRIPTION

The present disclosure includes apparatuses, methods, and systems for adjusting a sensing voltage in memory. An embodiment includes a memory having a group of memory cells, wherein a sub-group of the memory cells of the group remain programmed to a same data state, and circuitry configured to determine an amount of charge associated with the memory cells of the sub-group and adjust a voltage used to sense a data state of the memory cells of the group based, at least in part, on the determined amount of charge.

During the sensing of a memory cell, such as an FeRAM cell, a voltage (e.g., a read voltage) may be applied to the memory cell, and the data state of the cell can be determined based on the amount of current that flows through the cell in response to the applied voltage. For instance, the amount of current that flows through the cell in response to the applied read voltage can correspond to the polarization state of the ferroelectric material of the memory cell, which in turn can correspond to the data state of the cell. Accordingly, the read voltage may correspond to a voltage positioned between an expected voltage level of a signal output by a memory cell programmed to a first data state (e.g., a first polarization state) and an expected voltage level of a signal output by a memory cell programmed to a second data state (e.g., a second polarization state).

However, as such sense operations (e.g., read cycles) are performed on a memory cell (e.g., an FeRAM cell) during operation of the memory, the read voltage applied to the memory cell during each sense operation can cause the characteristics (e.g., behavior) of the ferroelectric material of the cell to change over time. If the read voltage is not adjusted (e.g., updated) to account for (e.g., track) this change in the ferroelectric material, the margin for sensing the data state of the cell may decrease, and the memory cell may eventually be determined (e.g., sensed) to be in a different data state (e.g. a different polarization state) than the state to which the cell was actually programmed. Such erroneous data sensing can reduce the performance and/or lifetime of the memory.

Embodiments of the present disclosure, however, can adjust (e.g., update) the read voltage to account for (e.g., track) changes that may occur in the ferroelectric material of FeRAM cells as a result of sense operations (e.g., read cycles) performed on the cells during operation of the memory. For example, embodiments of the present disclosure can adjust the read voltage based on an amount of charge associated with (e.g., stored by) a sub-group (e.g., portion) of memory cells of the memory that remain (e.g., are always) programmed to the same data state (e.g., the same polarization state) throughout the operation of the memory. An adjustment of the read voltage in such a manner can be performed quickly (e.g., as part of a sense operation being performed on the memory), and by utilizing components that add only a minimal amount of size and/or complexity to the circuitry of the memory. Accordingly, embodiments of the present disclosure can increase the performance and/or lifetime of the memory in a timely and cost-effective manner.

As used herein, “a” or “an” can refer to one or more of something, and “a plurality of” can refer to more than one of such things. For example, a memory cell can refer to one or more memory cells, and a plurality of memory cells can refer to two or more memory cells. Additionally, the designators “M” and “N” as used herein, particularly with respect to reference numerals in the drawings, indicates that one or more of the particular feature so designated can be included with embodiments of the present disclosure.

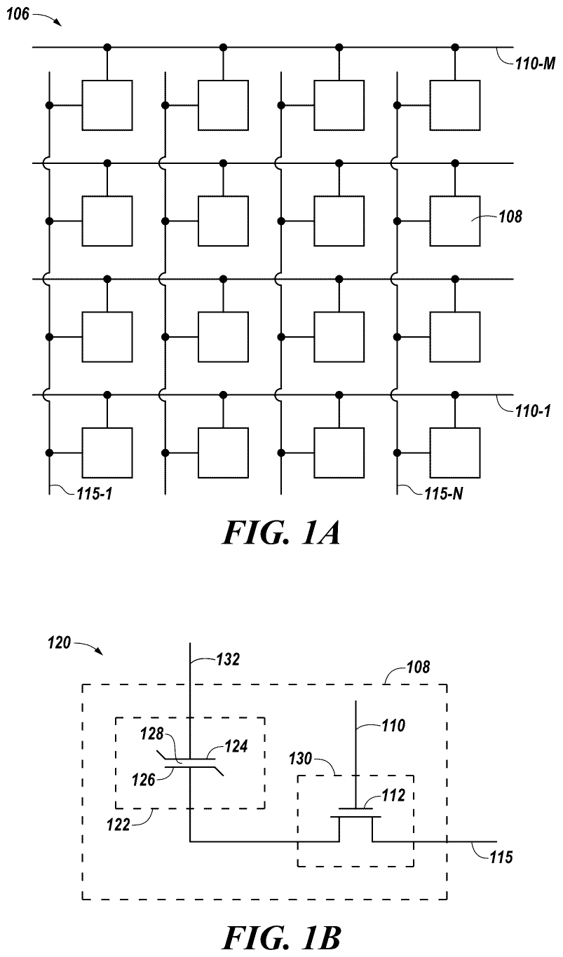

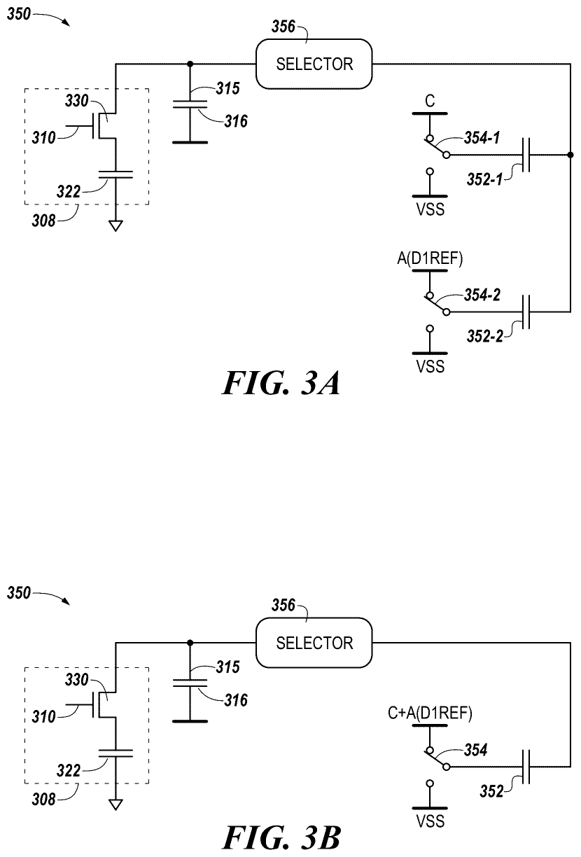

The figures herein follow a numbering convention in which the first digit or digits correspond to the drawing figure number and the remaining digits identify an element or component in the drawing. Similar elements or components between different figures may be identified by the use of similar digits. For example, 108 may reference element “08” in FIGS. 1A and 1B, and a similar element may be referenced as 308 in FIG. 3.

FIG. 1A illustrates an example of a memory array 106 in accordance with an embodiment of the present disclosure. Memory array 106 can be, for example, a ferroelectric memory (e.g., FeRAM) array.

As shown in FIG. 1A, memory array 106 may include memory cells 108 that may be programmable to store different states. Memory cells 108 can be, for example, FeRAM cells. A memory cell (e.g., a FeRAM cell) 108 may include a capacitor to store a charge representative of the programmable states. For example, a charged and uncharged capacitor may respectively represent two logic states (e.g. 0 and 1). A memory cell 108 may include a capacitor with a ferroelectric material, such as, for instance, an oxide material such as lead zirconate titanate (PZT) in some examples. For example, ferroelectric materials may have a non-linear relationship between an applied electric field and stored charge (e.g., in the form of a hysteresis loop), and may have a spontaneous electric polarization (e.g., a non-zero polarization in the absence of an electric field). Different levels of charge of a ferroelectric capacitor may represent different logic states, for example.

As shown in FIG. 1A, a memory cell 108 may be coupled to a respective access line, such as a respective one of access lines 110-1 to 110-M, and a respective data (e.g., digit) line, such as one of data lines 115-1 to 115-N. For example, a memory cell 108 may be coupled between an access line 110 and a data line 115. In an example, access lines 110 may also be referred to as word lines, and data lines 115 may also be referred to as bit lines. Access lines 110 and data lines 115, for example, may be made of conductive materials, such as copper, aluminum, gold, tungsten, etc., metal alloys, other conductive materials, or the like.

In an example, memory cells 108 commonly coupled to an access line 110 may be referred to as a row of memory cells. For example, access lines 110 may be coupled to a row decoder (not shown in FIG. 1A), and data lines 115 may be coupled to a column decoder (not shown in FIG. 1A). Operations such as programming (e.g., writing) and sensing (e.g., reading) may be performed on memory cells 108 by activating or selecting the appropriate access line 110 and a data line 115 (e.g., by applying a voltage to the access line). Activating an access line 110 may electrically couple the corresponding row of memory cells 108 to their respective data lines 115.

Although not shown in FIG. 1A for clarity and so as not to obscure embodiments of the present disclosure, memory array 106 can be included in an apparatus in the form of a memory device. As used herein, an “apparatus” can refer to, but is not limited to, any of a variety of structures or combinations of structures, such as a circuit or circuitry, a die or dice, a module or modules, a device or devices, or a system or systems, for example. Further, the apparatus (e.g., memory device) may include an additional memory array(s) analogous to array 106.

FIG. 1B illustrates an example circuit 120 that includes a memory cell 108 in accordance with an embodiment of the present disclosure. As shown in FIG. 1B, circuit 120 may include a memory (e.g., FeRAM) cell 108, an access line 110, and a data line 115 that may respectively be examples of a memory cell 108, an access line 110, and a data line 115, shown in FIG. 1A.

As shown in FIG. 1B, memory cell 108 may include a storage element, such as a capacitor 122, that may have a first plate, such as a cell plate 124, and a second plate, such as a cell bottom 126. Cell plate 124 and cell bottom 126 may be capacitively coupled through a ferroelectric material 128 positioned between them. The orientation of cell plate 124 and cell bottom 126 may be flipped without changing the operation of memory cell 108.

As shown in FIG. 1B, circuit 120 may include a select device 130, such as a select transistor. For example, the control gate 112 of select device 130 may be coupled to access line 110. In the example of FIG. 1B, cell plate 124 may be accessed via plate line 132, and cell bottom 126 may be accessed via data line 115. For example, select device 130 may be used to selectively couple data line 115 to cell bottom 126 in response to access line 110 activating select device 130. For example, capacitor 122 may be electrically isolated from data line 115 when select device 130 is deactivated, and capacitor 122 may be electrically coupled to data line 115 when select device 130 is activated. Activating select device 130 may be referred to as selecting memory cell 108, for example.

In an example, sources of an electric field, such as positive or negative electrical pulses (e.g., positive or negative voltage or current pulses), can be applied to the storage element of memory cell 108 (e.g., to capacitor 122) for a particular duration to program the cell to a target data state. For instance, when the electric field (e.g., the electrical pulses) is applied across the ferroelectric material 128 of capacitor 122, the dipoles of ferroelectric material 128 may align in the direction of the applied electric field. The dipoles may retain their alignment (e.g., polarization state) after the electric field is removed, and different logic states (e.g., 0 and 1) may be stored as the different polarization states of the ferroelectric material 128. Accordingly, memory cell 108 may be programmed by charging cell plate 124 and cell bottom 126, which may apply an electric field across ferroelectric material 128 and place the ferroelectric material in a particular polarization state (e.g., depending on the polarity of the applied field) that may correspond to a particular data (e.g., logic) state. The data state of the memory cell may subsequently be determined (e.g., sensed) by determining which polarization state the ferroelectric material is in.

For example, when a sensing (e.g., read) voltage is applied to the memory cell (e.g., during a sense operation being performed on the cell), current may flow through, and be output by, the memory cell in response to the sensing voltage being applied to the cell. This current can correspond to the amount of charge discharged by the memory cell (e.g. by the capacitor of the memory cell) while the sensing voltage is being applied to the memory cell. As such, the data state of the memory cell can be determined based on the amount of current output by the memory cell (e.g., the amount of charge discharged by the memory cell) while the sensing voltage is being applied to the memory cell

For instance, the current output by the memory cell may be a first (e.g., low) amount if the memory cell has been programmed to a first data state (e.g., 1) corresponding to a first polarization state of the ferroelectric material of the memory cell, and the current output by the memory cell may be a second (e.g., high and/or greater) amount if the memory cell has been programmed to a second data state (e.g., 0) corresponding to a second polarization state of the ferroelectric material of the memory cell. As used herein, the first polarization state may be referred to as a displacement state, and may correspond to a polarization state in which the alignment of the dipoles of the ferroelectric material of the memory cell do not change in response to the sensing voltage being applied to the cell. The second polarization state may be referred to as a switching state, and may correspond to a polarization state in which the alignment of the dipoles of the ferroelectric material of the memory cell changes (e.g., switch and/or flip) in response to the sensing voltage being applied to the cell.

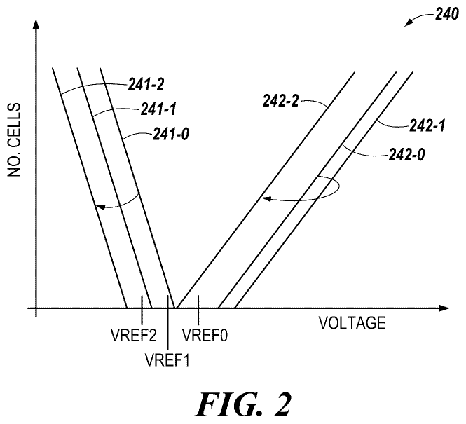

FIG. 2 illustrates a diagram 240 of a number of charge level distributions and sensing voltages associated with a group of memory cells in accordance with an embodiment of the present disclosure. The group of memory cells can be, for example, a page (e.g., a logical page) of memory cells, such as, for instance, a page of memory cells (e.g., FeRAM cells) 108 previously described in connection with FIGS. 1A and 1B.

In the example illustrated in FIG. 2, distributions 241-0 and 242-0 are associated with the data states of the memory cells of the group at a first point in time (e.g., before the memory cells have undergone any read cycles and/or at the beginning of the lifetime of the memory cells), distributions 241-1 and 242-1 are associated with the data states of the memory cells of the group at a second (e.g., subsequent) point in time during operation of the memory cells (e.g., after the memory cells have undergone some quantity of read cycles), and distributions 241-2 and 242-2 are associated with the data states of the memory cells of the group at a third (e.g., further subsequent) point in time during operation of the memory cells (e.g., after the memory cells have undergone a large quantity of read cycles and/or toward the end of the lifetime of the memory cells). For instance, distributions 241-0 and 242-0 are associated with the data states of the memory cells of the group before the characteristics (e.g., behavior) of the ferroelectric material of the cells have changed, and distributions 241-1, 242-1, 241-2, and 242-2 are associated with the data states of the memory cells of the group after the characteristics of the ferroelectric material of the cells have changed (e.g., due to the read cycles performed on the cells). Distributions 241-0, 241-1, and 241-2 may be collectively referred to herein as distributions 241, and distributions 242-0, 242-1, and 242-2 may be collectively referred to herein as distributions 242.

As an example, the charge level distributions shown in FIG. 2 can correspond to single level (e.g., two-state) memory cells. However, embodiments of the present disclosure are not limited to single level memory cells. For example, embodiments of the present disclosure can include multilevel cells such as, for instance, triple level cells (TLCs), or quadruple level cells (QLCs). In such examples, the diagram illustrated in FIG. 2 would include an additional distribution(s) (e.g., corresponding to each of the additional data states).

Charge level distributions 241 represent a first target data state (e.g., 1) to which the memory cells of the group can be programmed, and charge level distributions 242 represent a second target state (e.g., 0) to which the memory cells of the group can be programmed. Embodiments of the present disclosure, however, are not limited to these particular data assignments. The first target data state can correspond to the displacement (e.g., non-switching) polarization state of the ferroelectric material of the memory cells, and the second target data state can correspond to the switching polarization state of the ferroelectric material of the memory cells.

For example, distribution 241-0 represents the magnitudes of the charge levels to which the memory cells are programmed to for the first (e.g., displacement) data state at the first point in time, distribution 241-1 represents the magnitudes of the charge levels to which the memory cells are programmed to for the first data state at the second point in time, and distribution 241-2 represents the magnitudes of the charge levels to which the memory cells are programmed to for the first data state at the third point in time. Further, distribution 242-0 represents the magnitudes of the charge levels to which the memory cells are programmed to for the second (e.g., switching) data state at the first point in time, distribution 242-1 represents the magnitudes of the charge levels to which the memory cells are programmed to for the second data state at the second point in time, and distribution 242-2 represents the magnitudes of the charge levels to which the memory cells are programmed to for the second data state at the third point in time.

During a sense (e.g., read) operation to determine the respective data states stored by the memory cells of the group, a read voltage located between the two charge level distributions 241 and 242 can be used to distinguish between the two data states (e.g., between states 1 and 0). For instance, the read voltage may be applied to the memory cell, and the data state of the cell can be determined based on the amount of current that flows through the cell in response to the applied voltage, as previously described herein.

For example, at the first point in time, read voltage VREF0 shown in FIG. 2 can be used to distinguish between the two data states. However, once the characteristics of the ferroelectric material of the memory cells begin to change, the margin for sensing the data states of the memory cells of the group may change, and using VREF0 as the read voltage to sense the data states of the memory cells of the group may result in some of the cells being sensed to be in a state to which they were not actually programmed. For instance, a memory cell programmed to the second data state (e.g., 0), but whose charge level is to the left of VREF0 within distribution 242-2 (e.g., at the third point in time), may be erroneously sensed to be in the first data state (e.g., 1).

Embodiments of the present disclosure, however, can adjust (e.g., update) the read voltage to account for (e.g., track) changes in the characteristics of the ferroelectric material of the memory cells, in order to improve the sensing margin and reduce the likelihood of the data states of the memory cells of the group being read incorrectly due to these changes (e.g. due to the read cycles performed on the cells). For example, embodiments of the present disclosure can adjust the read voltage to VREF1 (e.g., between distributions 241-1 and 242-1) to distinguish between the two data states at the second point in time, and adjust the read voltage to VREF2 (e.g. between distributions 241-2 and 242-2) to distinguish between the two data states at the third point in time.

For example, a sub-group of the group of memory cells can remain (e.g., always be) programmed to the same data state (e.g., the same polarization state) throughout their operation. The sub-group of memory cells can comprise a portion (e.g., less than all) of the memory cells of the group. The data state to which the memory cells of the sub-group are programmed to can be the displacement (e.g., non-switching) polarization state (e.g., data state 1). Further, in some embodiments, the sub-group of memory cells being programmed to the same data state can refer to the average data state of the cells of the sub-group remaining the same over time. In such an example, the memory cells of the sub-group can be in different states, and the state of the cells can change over time, but the overall average state of the cells of the sub-group would always remain the same.

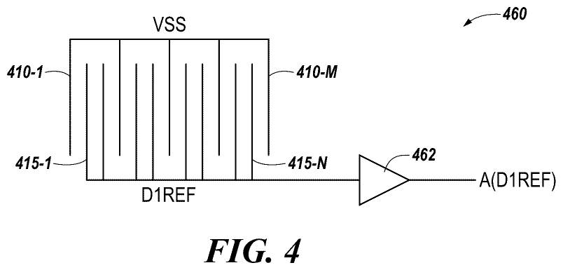

Before (e.g., immediately preceding) and/or during a sense (e.g., read) operation to determine the data states stored by the memory cells of the group, the amount of charge associated with (e.g., stored by) the memory cells of the sub-group can be determined (e.g., read), and the read voltage (e.g., VREF) used to distinguish between the two data states of the memory cells of the group can be adjusted based, at least in part, on the determined amount of charge. For instance, the adjusted read voltage can be a function of the determined amount of charge. The data states of the memory cells of the group can then be sensed using the adjusted read voltage. Circuitry that can be utilized to determine the amount of charge and adjust the read voltage will be further described herein (e.g., in connection with FIGS. 3A, 3B, and 4).

For example, the read voltage can be adjusted by adding a voltage value associated with the determined amount of charge to a constant voltage value (e.g., the adjusted read voltage can be the sum of the constant voltage value and the voltage value associated with the determined amount of charge). The voltage value associated with the determined amount of charge can be, for example, a function (e.g., a gain function) of the determined amount of charge. The gain function can be a numerical value between 0 and 5, for instance. The constant voltage value can be between 0.0 Volts and 3.0 Volts, for instance.

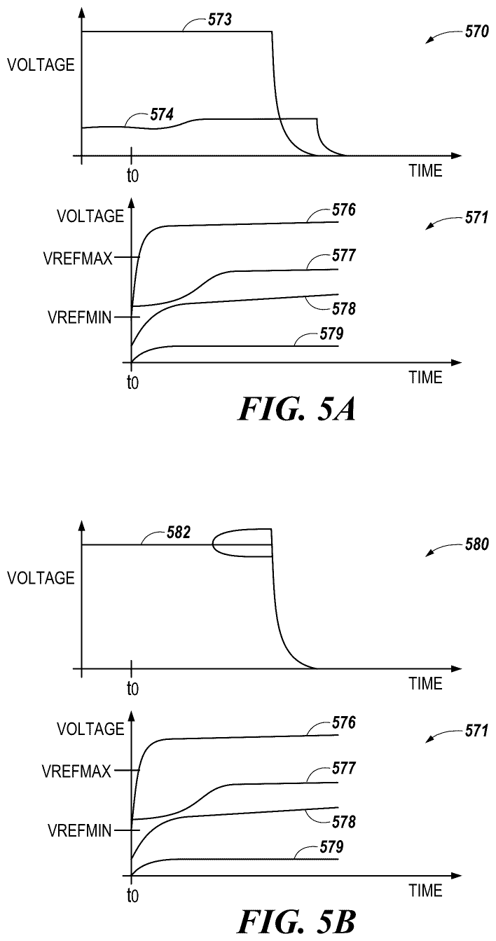

In some embodiments, the read voltage can be adjusted by generating a first voltage signal having the constant voltage value, and generating a second (e.g., separate) voltage signal that is (e.g., has a voltage value that is) a function (e.g., the gain function) of the determined amount of charge. That is, in such embodiments, the voltage value associated with the determined amount of charge can correspond to the second voltage signal, and the constant voltage value can correspond to the first voltage signal. In such embodiments, a first capacitor can be coupled to the first voltage signal and a second capacitor can be coupled to the second voltage signal, and the data states of the memory cells of the group can be sensed by applying the voltage signal of the first capacitor to the read voltage and applying the voltage signal of the second capacitor to the read voltage while applying the voltage signal of the first capacitor to the read voltage, as will be further described herein (e.g., in connection with FIGS. 3A and 5A). Further, an amplifier can be used to generate the second voltage signal, as will be further described herein (e.g., in connection with FIG. 4).

In some embodiments, the read voltage can be adjusted by generating a single (e.g., combined) voltage signal that is (e.g., has a voltage value that is) a function (e.g., the gain function) of the determined amount of charge and the constant voltage value. That is, in such embodiments, the voltage value associated with the determined amount of charge and the constant voltage value can correspond to a single (e.g., combined) voltage signal. In such embodiments, a single capacitor can be coupled to the single voltage signal, and the data states of the memory cells of the group can be sensed by applying the voltage signal of the single capacitor to the read voltage, as will be further described herein (e.g., in connection with FIGS. 3B and 5B). Further, an amplifier can be used to generate the voltage signal, as will be further described herein (e.g., in connection with FIG. 4).

The amount of charge associated with the sub-group of memory cells can be determined, for example, by applying a voltage to the access (e.g., word) lines of the sub-group of memory cells, and determining the amount of charge on the data (e.g., digit) lines of the sub-group of memory cells responsive to applying the voltage to the access lines of the sub-group of memory cells, as will be further described herein (e.g., in connection with FIG. 4). The data states of the memory cells of the group can be sensed by applying an additional voltage to the access lines of the group of memory cells after (e.g. 20 nanoseconds after) beginning to apply the voltage to the access lines of the sub-group, and applying the adjusted read voltage to the data lines of the group while applying the additional voltage to the access lines of the group. Examples of timing diagrams for determining the amount of charge associated with the sub-group and sensing the data states of the memory cells of the group will be further described herein (e.g., in connection with FIGS. 5A and 5B).

As previously noted, the amount of charge associated with the sub-group of memory cells can be determined, and the read voltage can be adjusted, before and/or during a sense operation to determine the data states stored by the memory cells of the group. For example, the amount of charge associated with the sub-group can be determined responsive to receiving a command (e.g., a row address activate command) to sense the data state of the memory cells of the group. Further, the amount of charge associated with the sub-group can again be determined, and the read voltage can be further adjusted, before and/or during additional (e.g., subsequent) sense operations (e.g., as the characteristics of the ferroelectric material of the memory cells continue to change). For example, the amount of charge associated with the sub-group can be determined responsive to receiving an additional command (e.g., a subsequent row address activate command) to sense the data state of the memory cells of the group, the read voltage can be further adjusted based, at least in part, on the amount of charge determined responsive to receiving the additional command, and the data states of the memory cells of the group can be sensed using the further adjusted read voltage.

In some embodiments the constant voltage value and/or the gain function used in the adjustment of the read voltage can be adjusted (e.g., modulated) during operation of the memory (e.g., between sense operations performed on the group of memory cells). For example, the constant voltage value can be decreased, and/or the gain can be increased, to overcompensate for the change in the characteristics of the ferroelectric material of the memory cells.

In some embodiments, the read voltage may be adjusted by no more than a particular (e.g., maximum) amount. This can prevent the sub-group of memory cells from experiencing a soft (e.g., transient) leakage event that could result in the read voltage adjustment reaching an extreme and inappropriate level.

FIGS. 3A and 3B illustrate examples of circuitry 350 for adjusting a sensing voltage in memory, in accordance with an embodiment of the present disclosure. Circuitry 350 can be coupled to, and be included in the same apparatus (e.g., memory device) as, memory array 106 previously described in connection with FIGS. 1A-1B.

For example, as illustrated in FIGS. 3A and 3B, circuitry 350 can be coupled to an array that includes memory cells 308 that are analogous to memory cells 108 previously described in connection with FIGS. 1A-1B. For instance, as illustrated in FIGS. 3A and 3B, memory cell 308 can include a storage element (e.g., capacitor) 322, and a select device 330 coupled to an access line 310 and data (e.g., digit) line 315, in a manner analogous to that previously described in connection with FIGS. 1A-1B. Although a single memory cell 308 is shown in FIGS. 3A and 3B for simplicity and so as not to obscure embodiments of the present disclosure, circuitry 350 can be coupled to each respective memory cell of the array.

Further, although not shown in FIGS. 3A and 3B for simplicity and so as not to obscure embodiments of the present disclosure, circuitry 350 and/or the memory array that includes cells 308 can be coupled to a controller. The controller can include, for example, control circuitry and/or logic (e.g., hardware and/or firmware), and can be included on the same physical device (e.g., the same die) as the memory array, or can be included on a separate physical device that is communicatively coupled to the physical device that includes the memory array. In an embodiment, components of the controller can be spread across multiple physical devices (e.g., some components on the same die as the array, and some components on a different die, module, or board). The controller can operate circuitry 350 to adjust a sensing (e.g., read) voltage used to sense a data state of memory cell 308, as described herein.

For instance, in the example shown in FIG. 3A, circuitry 350 can include a first capacitor 352-1 and a second capacitor 352-2, and in the example illustrated in FIG. 3B, circuitry 350 can include a single capacitor 352. Capacitors 352-1, 352-2, and 352 may be referred to herein as reference capacitors. Capacitors 352-1 and 352-2 in FIG. 3A, and capacitor 352 in FIG. 3B, can be coupled to memory cell 308 (e.g., via data line 315) through selector 356, as illustrated in FIGS. 3A and 3B, respectively. Selector 356 can be, for example, a shunt comprising a number of switches.

Further, in the example shown in FIG. 3A, circuitry 350 can include a first switch 354-1 coupled to capacitor 352-1 and a second switch 354-2 coupled to capacitor 352-2, and in the example illustrated in FIG. 3B, circuitry 350 can include a single switch 354 coupled to capacitor 352. Switches 354-1 and 354-2 in FIG. 3A, and switch 354 in FIG. 3B, can also be coupled to memory cell 308 through selector 356, as illustrated in FIGS. 3A and 3B, respectively.

Capacitors 352-1, 352-2, and 352, and switches 354-1, 354-2, and 354, can be used to adjust a sensing (e.g., read) voltage used to sense a data state of memory cell 308. For instance, in the example illustrated in FIG. 3A, capacitor 352-1 can be coupled to a first voltage signal (e.g., C) via switch 354-1, and capacitor 352-2 can be coupled to a second voltage signal (e.g., A (D1REF)) via switch 354-2. The first voltage signal can have a constant voltage value (e.g., between 0.0 Volts and 3.0 Volts), as previously described herein. The second voltage signal can be (e.g., have a voltage value that is) a function (e.g., A) of an amount of charge (e.g., D1REF) associated with (e.g., stored by) a sub-group of memory cells 308, as previously described herein. For instance, the function can be a gain function (e.g., a numerical value between 0 and 5), as previously described herein. The generation of the second voltage signal will be further described herein (e.g., in connection with FIG. 4).

In the example illustrated in FIG. 3A, the data state of memory cell 308 can be sensed by concurrently applying the voltage signal of capacitor 352-1 (e.g., C) and the voltage signal of capacitor 352-2 (e.g., A(D1REF)) to the read voltage. For instance, the first voltage signal can charge capacitor 352-1, and the second voltage signal can charge capacitor 352-2. The discharge from capacitor 352-1 can be added to (e.g., summed with) the discharge from capacitor 352-2, and the summed value (e.g., C+A(D1REF)) can be applied to memory cell 308 (e.g., via selector 356 and data line 315) as the adjusted read voltage.

In the example illustrated in FIG. 3B, capacitor 352 can be coupled, via switch 354, to a voltage signal (e.g., C+A(D1REF)) that combines the constant voltage value and the function of the amount of charge associated with the sub-group of memory cells. That is, the voltage signal coupled to capacitor 352 in FIG. 3B can be a function of the amount of charge associated with the sub-group of memory cells and the constant voltage value. The generation of the voltage signal will be further described herein (e.g., in connection with FIG. 4).

In the example illustrated in FIG. 3B, the data state of memory cell 308 can be sensed by applying the voltage signal of capacitor 352 to the read voltage. For instance, the voltage signal can charge capacitor 352, and the discharge from capacitor 352 (e.g., C+A(D1REF)) can be applied to memory cell 308 (e.g., via selector 356 and data line 315) as the adjusted read voltage.

Further, capacitors 352-1, 352-2, and 352 can be coupled to a common voltage supply (e.g., VSS) via switches 354-1, 354-2, and 354, respectively. For instance, switch 354-1 can be coupled to the voltage supply when not coupled to the first voltage signal (e.g., C), switch 354-2 can be coupled to the voltage supply when not coupled to the second voltage signal (e.g., A(D1REF)), and switch 354 can be coupled to the voltage supply when not coupled to the combined voltage signal (e.g., C+A(D1REF)).

FIG. 4 illustrates an example of circuitry 460 for determining (e.g., reading) an amount of charge associated with (e.g., stored by) a sub-group of memory cells, in accordance with an embodiment of the present disclosure. The sub-group of memory cells can comprise a portion of a group of memory cells, such as a portion of a group of memory cells 108 previously described in connection with FIGS. 1A-1B, and can remain programmed to the same data state during their operation, as previously described herein.

As shown in FIG. 4, circuitry 460 can include a plurality of access (e.g., word) lines 410-1 to 410-M, and a plurality of data (e.g., digit) lines 415-1 to 415-N, which can be analogous to access lines 110 and data lines 115, respectively, previously described in connection with FIGS. 1A-1B. The memory cells of the sub-group can be coupled to a respective access line 410 and a respective data line 415, as previously described herein (e.g., in connection with FIGS. 1A-1B).

As shown in FIG. 4, a read voltage (e.g., VSS) can be applied to the word lines 410 of the sub-group. Read voltage VSS can be, for example, common voltage supply VSS previously described in connection with FIGS. 3A-3B. Applying the read voltage to the word lines 410 can cause the data lines 415 of the group to charge. The total amount of charge on the data lines 415 (e.g., D1REF) responsive to the read voltage being applied to word lines 410 can correspond to (e.g., be) the amount of charge associated with the memory cells of the sub-group.

As shown in FIG. 4, the amount of charge associated with the memory cells of the sub-group (e.g., D1REF) can be input into an amplifier 462 of circuitry 460. Amplifier 462 can generate (e.g., output) a voltage signal (e.g., A(D1REF)) that is a function (e.g., a gain function) of the amount of charge associated with the memory cells of the sub-group. For instance, the voltage signal generated by amplifier 462 can be the second voltage signal previously described in connection with FIG. 3A, and can be a portion of the combined voltage signal previously described in connection with FIG. 3B.

FIGS. 5A and 5B illustrate examples of timing diagrams 570, 571, and 580 associated with adjusting a sensing voltage in memory in accordance with an embodiment of the present disclosure. The memory can comprise, for example, an array of memory cells 108 previously described in connection with FIGS. 1A-1B.

As shown in FIGS. 5A and 5B, timing diagram 571 includes waveforms 576, 577, 578, and 579. Waveform 576 represents a voltage signal (e.g., pulse) applied to the access (e.g., word) lines of a sub-group of memory cells at time t0, and waveform 578 represents a voltage signal applied to the plate lines of the sub-group of memory cells at time t0. The sub-group of memory cells can comprise a portion of a group of memory cells 108, as previously described herein. For instance, the sub-group of memory cells can be sub-group previously described in connection with FIG. 4, and the voltage signal applied to the word lines can be voltage VSS previously described in connection with FIG. 4.

Waveform 579 represents (e.g., corresponds to) the total amount of charge on the data (e.g., digit) lines of the sub-group of memory cells responsive to the voltage signals being applied to the word lines and plate lines of the sub-group, which can correspond to (e.g., be) the amount of charge associated with the memory cells of the sub-group, as previously described herein. For instance, waveform 579 can correspond to D1REF previously described in connection with FIG. 4.

Waveform 577 represents a voltage signal that is a function (e.g., a gain function) of the amount of charge associated with the memory cells of the sub-group. For instance, waveform 577 can correspond to voltage signal A(D1REF) generated by amplifier 462 previously described in connection with FIG. 4. As shown in FIGS. 5A and 5B, this voltage signal can be (e.g., remain) between VREFMIN and VREFMAX. VREFMIN can correspond to a voltage amount that is the minimum amount of voltage needed for the sensing voltage to distinguish between the data states of the memory cells, and VREFMAX can correspond to a voltage amount that is the maximum amount to which the sensing voltage can be adjusted to distinguish between the data states of the memory cells (e.g., the maximum amount described in connection with FIG. 2).

In the example shown in FIG. 5A, timing diagram 570 includes waveforms 573 and 574. Waveform 573 represents a voltage signal having a constant voltage value, and waveform 574 represents a voltage signal having a voltage value that is a function of the amount of charge associated with the memory cells of the sub-group. For instance, waveform 573 can correspond to the first voltage signal (e.g., C) previously described in connection with FIG. 3A, and waveform 574 can correspond to the second voltage signal (e.g., A(D1REF) previously described in connection with FIG. 3A.

The voltage signals represented by waveforms 573 and 574 can be used to adjust the sensing voltage used to sense the data states of the memory cells of the group. For example, after time t0 illustrated in FIG. 5A (e.g., 20 nanoseconds after time t0), the voltage signals (e.g., separate voltage signals) represented by waveforms 573 and 574 can be concurrently applied to the sensing voltage to sense the data states of the memory cells of the group, as previously described herein. For instance, the separate voltage signals represented by waveforms 573 and 574 can be concurrently applied to the sensing voltage, as previously described in connection with FIG. 3A.

In the example shown in FIG. 5B, timing 580 includes waveform 582. Waveform 582 represents a voltage signal having voltage value that is a function of the amount of charge associated with the memory cells of the sub-group and a constant voltage value. For instance, waveform 582 can correspond to the voltage signal C+A(D1REF) previously described in connection with FIG. 3B.

The voltage signal represented by waveform 582 can be used to adjust the sensing voltage used to sense the data states of the memory cells of the group. For example, after time t0 illustrated in FIG. 5B (e.g., 20 nanoseconds after time t0), the voltage signal (e.g., combined voltage signal) represented by waveform 582 can be applied to the sensing voltage to sense the data states of the memory cells of the group, as previously described herein. For instance, the combined voltage signal represented by waveform 582 can be applied to the sensing voltage, as previously described in connection with FIG. 3B.

Although specific embodiments have been illustrated and described herein, those of ordinary skill in the art will appreciate that an arrangement calculated to achieve the same results can be substituted for the specific embodiments shown. This disclosure is intended to cover adaptations or variations of a number of embodiments of the present disclosure. It is to be understood that the above description has been made in an illustrative fashion, and not a restrictive one. Combination of the above embodiments, and other embodiments not specifically described herein will be apparent to those of ordinary skill in the art upon reviewing the above description. The scope of a number of embodiments of the present disclosure includes other applications in which the above structures and methods are used. Therefore, the scope of a number of embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
a memory having a group of memory cells, wherein a sub-group of the memory cells of the group remain programmed to a same data state; and
circuitry configured to:
determine an amount of charge associated with the memory cells of the sub-group; and
adjust a voltage used to sense a data state of the memory cells of the group based, at least in part, on the determined amount of charge.

2. The apparatus of claim 1, wherein the circuitry is configured to adjust the voltage used to sense the data state of the memory cells of the group by:
generating a first voltage signal having a constant voltage value; and
generating a second voltage signal that is a function of the determined amount of charge.

3. The apparatus of claim 2, wherein:
the circuitry includes a first capacitor coupled to the first voltage signal and a second capacitor coupled to the second voltage signal; and
the circuitry is configured to sense the data state of the memory cells of the group by:
applying a voltage signal of the first capacitor to the voltage used to sense the data state of the memory cells of the group; and
applying a voltage signal of the second capacitor to the voltage used to sense the data state of the memory cells while applying the voltage signal of the first capacitor to the voltage used to sense the data state of the memory cells.

4. The apparatus of claim 2, wherein the circuitry includes an amplifier configured to generate the first voltage signal.

5. The apparatus of claim 1, wherein the circuitry is configured to adjust the voltage used to sense the data state of the memory cells of the group by generating a single voltage signal that is a function of the determined amount of charge and a constant voltage value.

6. The apparatus of claim 5, wherein:
the circuitry includes a capacitor coupled to the single voltage signal; and
the circuitry is configured to sense the data state of the memory cells of the group by applying a voltage signal of the capacitor to the voltage used to sense the data state of the memory cells.

7. The apparatus of claim 1, wherein:
the group of memory cells comprises a page of memory cells; and
the sub-group comprises a portion of the memory cells of the page.

8. The apparatus of claim 1, wherein the memory cells of the group are ferroelectric memory cells.

9. A method of operating memory, comprising:
determining an amount of charge associated with a sub-group of memory cells of a memory, wherein:
the sub-group of memory cells comprise a portion of a group of memory cells of the memory; and
the sub-group of memory cells are programmed to a same data state;
adjusting a voltage used to sense a data state of the memory cells of the group based, at least in part, on the determined amount of charge; and
sensing the data state of the memory cells of the group using the adjusted voltage.

10. The method of claim 9, wherein the sub-group of memory cells are programmed to a displacement polarization state.

11. The method of claim 9, wherein the method includes determining the amount of charge associated with the sub-group of memory cells by:
applying a voltage to access lines of the sub-group of memory cells; and
determining an amount of charge on data lines of the sub-group of memory cells responsive to applying the voltage to the access lines of the sub-group of memory cells.

12. The method of claim 11, wherein the method includes sensing the data state of the memory cells of the group by:
applying an additional voltage to access lines of the group of memory cells after beginning to apply the voltage to the access lines of the sub-group of memory cells; and
applying the adjusted voltage to data lines of the group of memory cells while applying the additional voltage to the access lines of the group of memory cells.

13. The method of claim 9, wherein the method includes determining the amount of charge associated with the sub-group of memory cells responsive to receiving a command to sense the data state of the memory cells of the group.

14. The method of claim 13, wherein the method includes:
receiving an additional command to sense the data state of the memory cells of the group;
determining an amount of charge associated with the sub-group of memory cells responsive to receiving the additional command;
adjusting the voltage used to sense the data state of the memory cells of the group based, at least in part, on the amount of charge determined responsive to receiving the additional command; and
sensing the data state of the memory cells of the group using the adjusted voltage.

15. An apparatus, comprising:
a memory having a group of memory cells, wherein a sub-group of the memory cells of the group remain programmed to a same average data state; and
circuitry configured to:
determine an amount of charge associated with the memory cells of the sub-group; and
adjust a voltage used to sense a data state of the memory cells of the group by adding a voltage value associated with the determined amount of charge to a constant voltage value.

16. The apparatus of claim 15, wherein the voltage value associated with the determined amount of charge is a function of the determined amount of charge.

17. The apparatus of claim 15, wherein:
the constant voltage value corresponds to a first voltage signal; and
the voltage value associated with the determined amount of charge corresponds to a second voltage signal.

18. The apparatus of claim 15, wherein the voltage value associated with the determined amount of charge and the constant voltage value correspond to a single voltage signal.

19. The apparatus of claim 15, wherein the circuitry is configured to adjust the constant voltage value.

20. The apparatus of claim 15, wherein the circuitry is configured to adjust the voltage used to sense a data state of the memory cells of the group by no more than a particular amount.
